(19) United States
(12) Patent Application Publication
(10) Pub. No.: US 2007/0018633 A1
(43) Pub. Date: Jan. 25, 2007

(54) Probe use in electric test

(75) Inventors: Hideki Hirakawa, Aomori (JP); Akira Souma, Aomori (JP); Takayuki Hayashizaki, Aomori (JP); Shinji Kuniyoshi, Aomori (JP)

Correspondence Address: BACON & THOMAS, PLLC, 625 SLATERS LANE, FOURTH FLOOR, ALEXANDRIA, VA, 22314, US

(73) Assignee: KABUSHIKI KAISHA NIHON MICRONICS, Tokyo (JP)

(21) Appl. No.: 11/436,674

(22) Filed: May 19, 2006

(30) Foreign Application Priority Data
May 31, 2005 (JP) 2005-159332
Oct. 18, 2005 (JP) 2005-303090

(51) Int. Cl. G01R 31/02

(52) U.S. Cl. 324/72.5

(57) ABSTRACT

A probe comprises a body member having a front end area and supported on a support member in a cantilever state, and a tip member combined with the front end area of the body member. The tip member includes a base portion with at least a part of the tip member embedded in the front end area; a contact portion to be pressed against a device under test and projecting from the base portion in a second direction; and a reference portion formed at a position spaced apart from the contact portion in a first direction and projecting from the base portion in the second direction intersecting the first direction, and is made of a harder material than the body member.

### TECHNICAL FIELD

The present invention relates to probes for use in electric test of a flat plate-like device under test such as a semiconductor integrated circuit.

### BACKGROUND

A flat plate-like device under test such as a semiconductor integrated circuit undergoes an electric test as to whether it is produced as per specification. This type of electric test is conducted, using an electric connecting apparatus such as a probe card, a probe block, a probe unit and the like provided with a plurality of probes (contacts) to be pressed individually against electrodes of the device under test. This type of electrical connecting apparatus is used for electrically connecting electrodes of the device under test and a tester in an electric testing apparatus.

As a probe to be used in this type of electrical connecting apparatus, there is a blade type one made by using so-called photolithographic technique for exposing and developing a photoresist, and electroforming technique for electrically plating the portion where the photoresist was removed (Patent Document 1).

Patent Document 1

Japanese Patent Appln. Public Disclosure No. 2004-340654 Official Gazette

The above-mentioned blade type probe comprises a seat area (mounting portion) to be supported on a support member such as a wiring base plate or a ceramic base plate, an arm area (arm portion) extending from the lower end portion of the seat area in a first direction (lateral direction), and a tip area (tip portion) integrally continuing to the downside of the front end portion of the arm area, and is supported on the support portion in a cantilever state.

The tip area has a pedestal portion continuing to the downside of the front end portion of the arm area, a contact portion projecting downward from the underside of the pedestal portion, and a reference portion projecting downward from the underside of the pedestal portion.

In a state that the probes assembled into the electrical connecting apparatus are incorporated in the electric testing apparatus, the contact portions act as portions to be pressed against the electrodes of the device under test, and the reference portions are used as portions for detecting and determining positions of the probes, particularly, the front ends of the contact portions (i.e., tips) relative to the electric testing apparatus.

The foregoing conventional probes are pressed at their tips against the electrodes of the device under test at the time of testing with the electrical connecting apparatus incorporated into the electric testing apparatus. By this, an overdrive acts on the probes, the probes are curved in the arm area by elastic deformation, and the tips slide relative to the electrodes of the device under test.

The whole body of the conventional probes above is made of the same metal material. Therefore, if the probe is made of metal material of high tenacity (flexible) such as nickel and its alloy, the tip wears much, making the probe short-lived.

On the other hand, in case the probe is made of a metal of high strength such as rhodium, when an overdrive acts on the probe, the arm area is hard to elastically deform, so that a sliding amount of the tip relative to the device under test is small, and besides, the probe is easy to break in the arm area.

It is conceivable to make the contact portion and another portion of different metal materials and join both portions lastly. By doing so, however, it is difficult to join the contact portion and another portion so that the physical relationship between the front end of the contact portion, i.e., the tip, and the front end of the reference portion, i.e., the reference point, may become as per specification, and the reference portion cannot be fixed accurately at the tip position relative to the electric testing apparatus.

As mentioned above, the smaller and the more densely arranged the probes to be arranged in the electrical connecting apparatus are, the more difficult it is to join the contact portion and another portion so that the physical relationship between the tip and the reference point may be as per specification.

Also, if the tip area is made of a different material from the seat area and the arm area as mentioned above, a tip member forming the tip area and a body member forming the seat area and the arm area should be made by different processes. As a result, problems such as follows are caused.

In an electrical connecting apparatus with a plurality of probes, probes should be attached to a support member in order to make overdrives of the same magnitude act on the probes so as to make equal the pressing force (needle pressure) of the tips to electrodes of a device under test so that the height positions of the tips from the support member may be the same.

Furthermore, in order to make the tip area of a different material from the seat area and the arm area, the photolithographic process and the electroforming process should be performed at least twice for overlapping the tip member and the body member.

As a result, even if an accuracy in positioning a mask in the lithographic process is enhanced, an error by a dimension corresponding to an error (in positioning the mask) in at least overlapping of the tip member and the body member occurs in length dimension (i.e., height dimension) among the probes. It is very difficult to mount a plurality of probes having such a dimension error on the support member so that height positions of the tips from the support member may become uniform.

In view of the above, in the electric-connecting apparatus using probes by fabrication of the tip area of a different material from that of the seat area and the arm area, a work of grinding the tips to make the height positions of the tips from the support member uniform is unavoidable after mounting the probes on the support member.

### SUMMARY

A first object of the present invention is, therefore, to facilitate elastic deformation in the arm area, in spite of constant physical relation between the tips and the reference points and a little amount of wear of the tips.

Further, a second object of the present invention is to enable to facilitate production of probes having the same length dimension, although the tip area can be made of a different material from that of the seat area and the arm area.

The probes according to a first invention includes a body member having a front end area and to be supported on a support member and a tip member combined with the front end area of the body member. The tip member includes: a base portion with at least a part embedded in the front end area; a contact portion to be pressed against a device under test and projecting from the base portion in a second direction intersecting a first direction; and a reference portion formed at a location at an interval from the contact portion in the first direction and projecting from the base portion in the second direction, and is made of a material harder than that of the body member.

When the tip member has the contact portion and the reference portion, multiple probes provided with the front end (tip) of the contact portion having the physical relation as per specification and the front end (reference point) of the reference portion can be easily and cheaply manufactured by making the tip member of a single material.

Also, when the body member and the tip member are made of different materials, it is possible to make the body member of a metal material of high tenacity such as nickel and its alloy, and to make the tip member of a metal material of high hardness such as rhodium. Therefore, in spite of a little amount of wear at the tip, the body portion tends to elastically deform when an overdrive acts, and a sliding amount of the tip relative to electrodes of the device under test becomes great.

The body member may further have a seat area having one end to be mounted on the support member and the other end opposite thereto, and an arm area extending from the other end of the seat area in the first direction, and the front end area may project from the front end of the arm area in the same direction as the contact portion of the tip member and the reference portion. By doing so, the probes are supported on the support member in a cantilever state, and surely deforms in the arm area when an overdrive acts.

The base portion of the tip member may be embedded in the front end area such that the contact portion and the reference portion project from the front end area in the second direction. By doing so, since the combined area of the tip member and the body member becomes large, bonding force of both members becomes great.

Each of the contact portion and the reference portion may have an end face directed to the side opposite to the base portion, and the end face of the reference portion may be retreated toward the base portion from the level of the end face of the contact portion. By doing so, even if the end face or the tip of the contact portion is pressed against the electrodes of the device under test, the reference portion does not contact the device under test and its electrodes, thereby preventing the reference portion from being damaged.

The body member may be made of a metal material selected from nickel, its alloy and phosphor bronze, and the tip member may be made of a metal material selected from cobalt and rhodium and their alloys.

The probes according to a second invention includes: a body member having a seat area to be mounted on the support member and the body member having an arm area extending from the lower end of the seat area in the lateral direction; a tip member having a tip projecting downward from the front end of the arm area; and at least one reference member having a reference portion projecting upward from the seat area. The tip member and the reference member are made of the same material which is different from that of the seat area.

A part of the reference member may be embedded in the body member.

The probes may have at least two reference members including the reference portions of the same height level at an interval in the lateral direction.

The reference portions can include flat upper faces of the same height level.

The materials of the tip member and the reference member may be made of a material harder than that of the body member.

The tip member can include a base portion at least a part of which is embedded in the arm area, a contact portion to be pressed against a device under test and projecting downward from the base portion, and a reference portion formed at a location spaced apart from the contact portion in the lateral direction and projecting downward from the base portion.

If the tip member and the reference member are made of the same material which is different from that of the body member, the tip member and the reference member can be made by the same photolithographic process and the same electroforming process.

If the tip member and the reference member are thus made by the same process simultaneously, it is possible to manufacture the tip member and the reference member by use of the same mask, so that, regardless of accuracy in overlapping the tip member and the reference member on the body member, the physical relation between the tip and the reference portion becomes constant. As a result, although the material of the tip area can be different from that of the seat area and the arm area, probes with the same length dimension can be easily made.

If the tip member and the reference member can be made of a different material from that of the body member, it is possible to make the tip member and the reference member of a highly hard material such as rhodium and the body member of a highly tenacious (flexible) material such as nickel or its alloy. This enables to make the body member easily elastically deformable under overdrive in spite of a little wear at the tip, and to obtain probes with a great sliding amount at the tip relative to electrodes of a device under test.

If a part of the reference member is embedded in the body member, bonding strength between the reference member and the body member becomes strong, thereby preventing the reference member from peeling off the body member.

If the probe has at least two reference members spaced apart in the lateral direction and of the same height level, the reference portions of the probe can be mounted on a support member with the reference portions of the probe abutted on the support member. This facilitates mounting of the probes on the support member and enables to make the height dimension from the support member to the tips of the probes equal.

If the reference portions include flat upper faces of the same height level, the probes become stable relative to the support member by making the upper faces abut the support member, so that by maintaining such a state, the probes can be easily and accurately mounted on the support member by means of soldering and the like.

If the tip member and the reference member are made of a material harder than that of the body member, the amount of wear at the tip becomes less.

The tip member can include a base portion at least a part of which is embedded in the arm area, a contact portion pressed against a device under test and projecting downward from the base portion, and a second reference portion formed at a location spaced apart from the contact portion in the lateral direction and projecting from the base portion in a forward and backward direction intersecting the vertical direction.

If at least a part of the base portion of the tip member is embedded in the arm area and the contact portion is projected downward from the base portion, the bonding strength between the tip member and the body member becomes strong, thereby preventing the tip member from peeling off the body member.

Also, if the tip member has the contact portion and the second reference portion, it is possible to produce easily and cheaply multiple probes each having the front end (the tip) of the contact portion and the front end (the reference point) of the second reference portion which have the physical relationship as per specification.

### BRIEF DESCRIPTION OF THE DRAWINGS

FIG. 1 is a front elevation showing a first embodiment of the probe according to the present invention.

FIG. 2 is a bottom view of the probe shown in FIG. 1.

FIG. 3 is a left side view of the probe shown in FIG. 1.

FIG. 4 is a front view showing a second embodiment of the probe according to the present invention.

FIG. 5 is a left side view of the probe shown in FIG. 4.

FIG. 6 is a plan view of the probe shown in FIG. 4

FIG. 7 is a bottom view of the probe shown in FIG. 4.

FIG. 8 is a front elevation showing a third embodiment according to the present invention.

FIGS. 9 (A) through (F) are views for explaining one embodiment of the method of producing the probes.

FIG. 10 is a view for explaining another embodiment of the method of producing the probes.

### DETAILED DESCRIPTION OF EMBODIMENTS

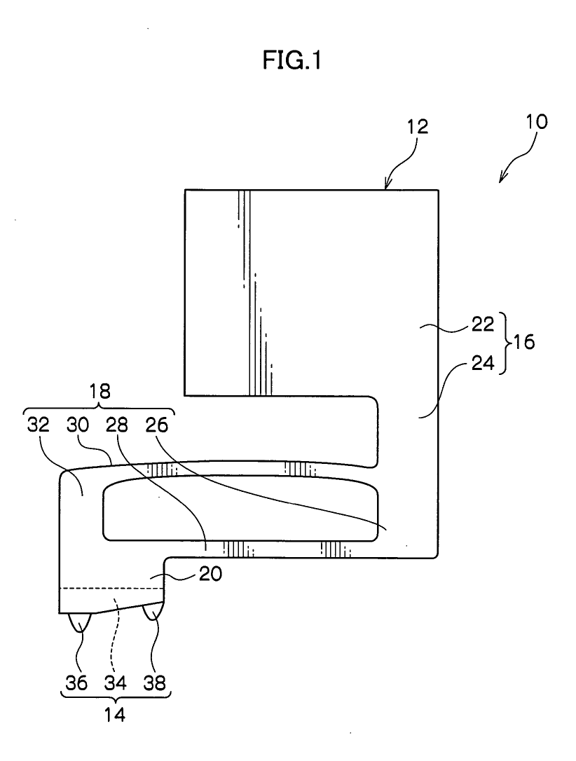

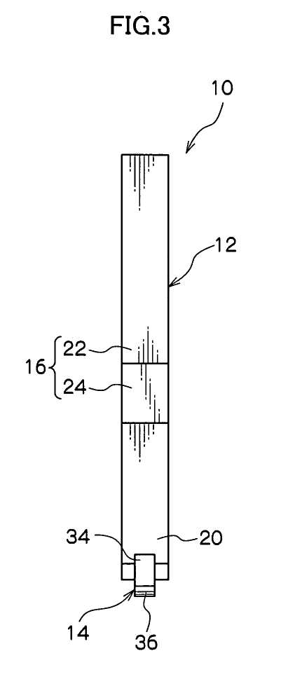

Below is explained a first invention in line with FIG. 1 through FIG. 3. In this explanation of the first invention, the rightward and leftward direction in FIG. 1 is called the lateral direction (the first direction), the upward and downward direction is called the vertical direction (the second direction), and the direction perpendicular to the sheet is called the forward and backward direction (the third direction). These directions are, however, different depending on a chuck top of a tester which receives a device under test to be electrified.

Referring to FIGS. 1 through 3, a probe 10 includes a body member 12 and a tip member 14, both members being formed to have a plate-like shape.

The body member 12 has a seat area 16, an arm area 18 extending from the lower end of the seat area 16 in the lateral direction, and a front end area 20 projecting downward from the front end of the art area 18.

The seat area 16 has a rectangular mounting portion 22 and an extension 24 extending downward from the lower end of the mounting portion 22, and continues integrally to the arm area 18 at the extension 24. The seat area 16 is mounted on a support member such as a wiring base plate or a ceramic base plate at the upper end of the mounting portion 22 so that the probe 10 as a whole may be formed like a cantilever.

The arm area 18 has one coupling portion 26 projecting downward from the lower end of the extension 24, and another coupling portion 32 integrally coupling upper and lower arm portions 28, 30 projected laterally from the coupling portion 26 at an interval from each other in the vertical direction and the front end of both arm portions 28, 30.

The front end area 20 is projected downward from the lower end of the arm portion 30 and the coupling portion 32 and acts as a pedestal or a seat. The lower end face of the front end area 20 is folded back like a V-shape, making an intermediate portion in the lateral direction a folding position.

The tip member 14 has a base portion 34 embedded in the front end area 20, a contact portion 36 projecting downward from the base portion 34, and a reference portion 38 projecting downward from the base portion 34. The base portion 34 has almost the same shape as the lower end portion of the front end area 20.

The contact portion 36 and the reference portion 38 extend in the forward and backward direction of the sheet as seen in FIG. 1, and are shaped like an inverted trapezoid in section. The contact portion 36 and the reference portion 38 are spaced apart in the lateral direction with the reference portion 38 positioned on the side of the coupling portion 26.

In the contact portion 36, its lower end face is made a tip to be pressed against a device under test. The lower end face of the reference portion 38 is used as a reference point for detecting and determining the position of the probe relative to an electric testing apparatus, in particular, the position of the tip, with the probe 10 assembled into the electrical connecting apparatus like the probe described in Patent Document 1.

The body member 12 is made of a metal material of high tenacity such as nickel, its alloy, phosphor bronze and the like, and the tip member 14 is made of a metal material of high hardness such as cobalt, rhodium, their alloys and the like.

In the probe 10, in a state of being assembled into the electrical connecting apparatus and into the electric testing apparatus, the lower end face of the reference portion 38 is detected by a sensor such as a video camera, and is located its coordinate position in the electric testing apparatus. The obtained coordinate position is used for detecting and determining the position of the probe relative to the electric testing apparatus, in particular, the position of the tip.

When the tip member 14 has the contact portion and the reference portion 38 such as the probe 10, the tip member 14 can be made of a single material, so that the physical relationship between the tip and the reference point can be made as per specification.

At the time of an electric test, the probe 10 has the lower end face (tip) of the contact portion 36 pressed against an electrode of a device under test. By this, overdrive acts on the probe 10.

The probe 10, with the body member 12, in particular, the arm portions 28, 30 made of a metal material of a high tenacity, is elastically deformed greatly in the art area 18, in particular, the arm portions 28, 30, and the lower end face of the contact portion 36 slides relative to the electrode of the device under test. The sliding amount at this time is great.

The lower end face of the contact portion 36, sliding relative to the electrode of the device under test, scrapes away an oxygen film formed on the electrode. At this time, since the tip member 14, in particular, the contact portion 36 is made of a metal material of high hardness, the amount of wear at the lower end face of the contact portion 36 is small, and the probe 10 has a long life.

In the probe 10, the lower end face of the reference portion 38 is retreated toward the base portion 34 than the lower end face of the contact portion 36. Because of this, even if the lower end face of the contact portion 36 is pressed against the electrode of the device under test, the reference portion 38 does not contact the device under test and its electrode, and is prevented from being damaged.

The probe 10, since the base portion 34 of the tip member 14 is embedded in the front end area 20, has high bonding strength between the body member 12 and the tip member 14.

The probe 10 such as mentioned above can be made by use of photolithographic technique and electroplating technique. Below is explained one example.

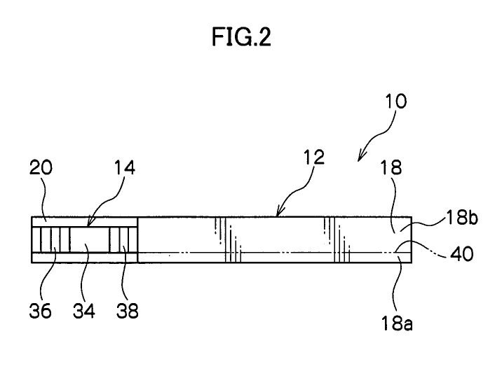

First, in the body member 12, a part 18a corresponding to the part below the two-dot chain line in FIG. 2 is made on a table-like base member (not shown) by photolithographic technique and electroforming technique.

Next, the tip member 14 is made on the part 18a by photolithographic technique and electroforming technique such that its base portion 34 comes above a portion corresponding to the front end area 20 of the part 18a and that the contact portion 36 and the reference portion 38 project from the portion corresponding to the front end area 20.

Then, in the body member 12, a part 18b corresponding to the part above the two-dot chain line in FIG. 2 is made on the part 18a and the base portion 34 of the tip member 14 by photolithographic technique and electroforming technique.

Finally, it suffices to remove the remaining resist, and to take off the produced probe 10 from the base.

As a result, the probe 10 with the base portion 34 of the tip member 14 embedded in the front end area 20 of the body member 12 and with the contact portion 36 and the reference portion 38 projecting downward from the front end area 20 of the body member 12 is produced.

In the probe 10 produced as mentioned above, the base portion 34 of the tip member 14 is integrally embedded in the front end area 20 of the body member 12, so that the bonding strength of the body member 12 and the tip member 14 is high.

By producing as mentioned above, the body member 12 and the tip member 14 can be made of different metal materials and the contact portion 36 and the reference portion 38 can be integrally produced at the same time, so that multiple probes having the same physical relationship between the contact portion 36 and the reference portion 38 can be produced in bulk and cheaply.

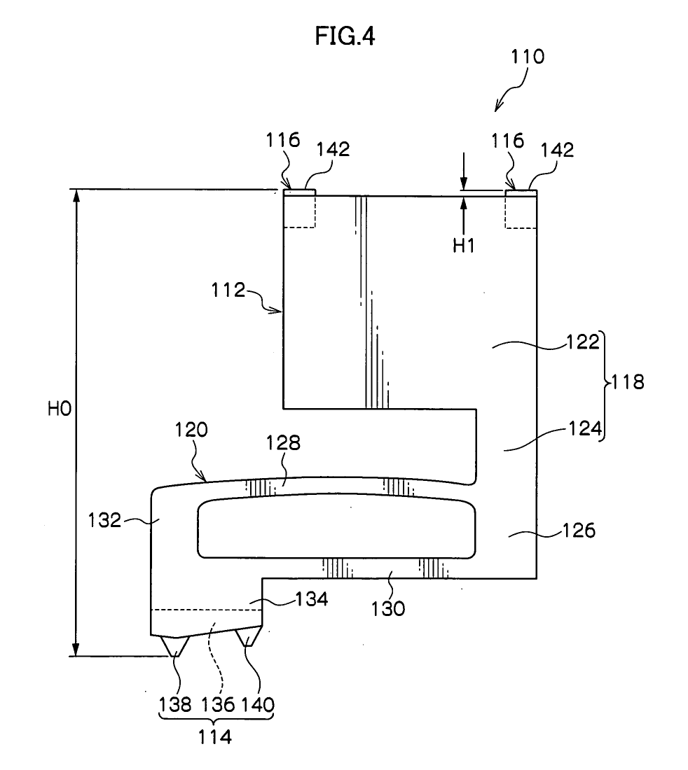

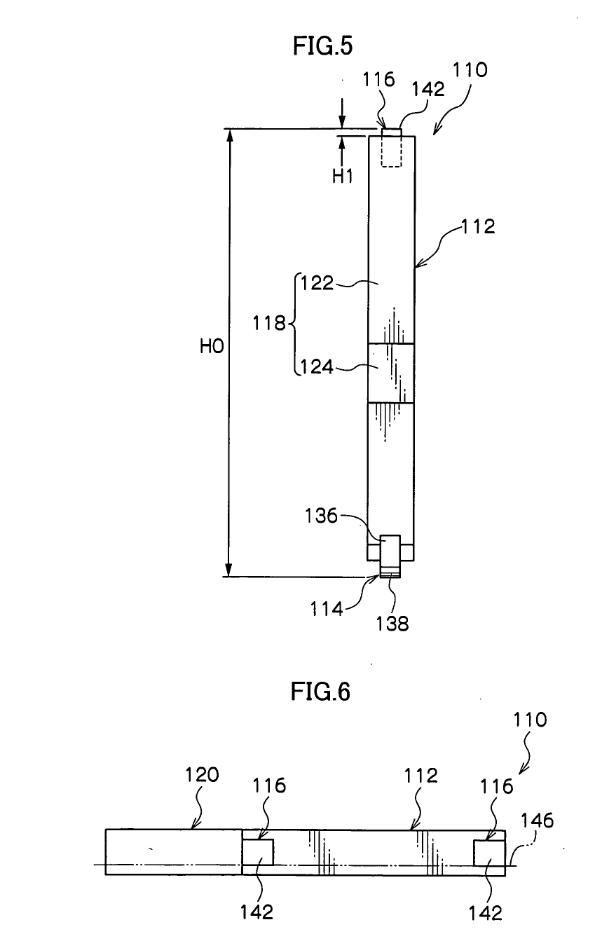

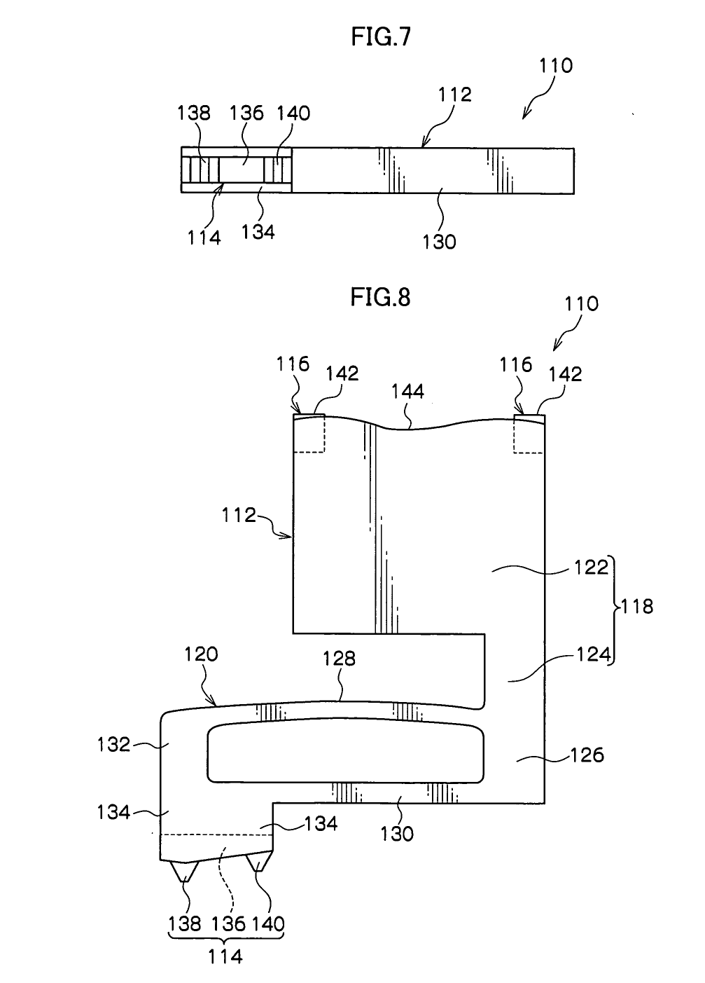

Below is explained the second invention in line with FIGS. 4 through 10. In the explanation of the second invention, the rightward and leftward direction in FIG. 4 is called the lateral direction or X direction (the first direction), the upward and downward direction is called the vertical direction or the Z direction (the second direction), and the direction perpendicular to the sheet of the drawing is called the thickness direction or the Y direction (the third direction). Those directions are different, however, by an attitude for disposing a base plate for display to be tested in a testing apparatus, namely, an attitude of the display base plate disposed in the testing apparatus.

Therefore, the above-mentioned directions may be determined such that, depending on the testing apparatus to dispose the probe, the X and Y directions are within any of a horizontal plane, an inclined plane inclined to the horizontal plane, and a perpendicular plain perpendicular to the horizontal plane, or a combination of those planes.

Referring to FIGS. 4 through 7, the probe 110 including a body member 112, a tip member 114 and two reference members 116 is formed to have a plate-like shape.

The body member 112 has a seat area 118 and an arm area 120 extending from the lower end portion of the seat area 118 in the lateral direction.

The seat area 118 has a rectangular mounting portion 122, an extension 124 integrally extending downward from the lower end of the mounting portion 122, and integrally continues in the extension 124 to the arm area 120. The seat area 118 is mounted on a support member such as a wiring base plate or a ceramic base plate at the upper end of the mounting portion 122 so that the probe 110 as a whole may be formed like a cantilever.

The arm area 120 has one coupling portion 120 projected downward from the lower end of the extension 124, upper and lower arm portions 128, 130 projected from the coupling portion 120 in the lateral direction at an interval from each other in the vertical direction, the other coupling portion 132 integrally coupling the front end portions of both arm portions 128 and 130, and a pedestal portion 134 projecting downward from the lower arm 130 and the coupling portion 132.

The pedestal portion 134 projects downward from the art portion 130 and the lower end portion of the coupling portion 132 and acts as a pedestal or a seat. The lower end face of the pedestal portion 134 is folded back like a V-shape with an intermediate portion in the lateral direction as a folding back position. The pedestal portion 134, therefore, corresponds to the front end area 20 of the probe 10 of the first invention.

The tip member 114 has a base portion 136 embedded in the pedestal portion 134, a contact portion 138 projecting downward from the base portion 136, and a reference portion 140 projecting downward from the base portion 136. The base portion 136 has about the same shape as the lower end portion of the pedestal portion 134.

The contact portion 138 and the reference portion 140 extend in the thickness direction, namely, the third (Y) direction and have an inverted trapezoidal shape in section. Because of this, the lower end faces of the contact portion 138 and the reference portion 140 are made flat planes. The contact portion 138 and the reference portion 140 are spaced apart from each other in the lateral direction such that the reference portion 140 is placed on the side of the coupling portion 126.

The lower end face of the contact portion 138 is made a tip to be pressed against a device under test. The lower end face of the reference portion 140 is used as a reference point for determining its position in the XY coordinate by detecting the position of the probe, in particular, the tip relative to the electric testing apparatus in a state that the probe 110 is assembled into the electrical connecting apparatus like the probe described in the patent document 1 and incorporated in the electric testing apparatus.

The reference portion 140 is retreated toward the base portion 136 higher than the level of the contact portion 138 so as not to contact a device under test even if the tip is pressed against the device under test.

A part of the reference member 116 is projected upward from the mounting portion 122, and the remaining portion is embedded in the mounting portion 122. The reference portion 116 has about the same thickness dimension as that of the tip member 114.

The upper faces of the reference members 116 are made to be flat reference portions 142 of the same height level. Therefore, even if the probes are made in bulk, a length dimension H0 from the tips of the probes to the reference portions 142 of the reference members 116, namely, the height positions of the reference portions 142 relative to the tips become the same. The reference portions 142 are, therefore, used as reference points for mounting the probes 110 on the support member.

An amount of projection H1 of the reference member 116 from the seat area 118 is 0.1 mm or less, and can be preferably made 0.05 mm or less.

The body member 112 is made of a metal material of high tenacity such as nickel and its alloy, phosphor bronze and the like. The tip member 114 is made of a metal material of high hardness such as cobalt, rhodium and their alloys.

The probe 110 is mounted at the upper end portion of the mounting portion 122 on the downside of a plate-like support member such as a wiring base plate and a probe base plate with a conductive adhesive such as solder so as to perpendicularly extend downward from the underside of the support member. Thereby, the probes are assembled into the electrical connecting apparatus.

According to the probe 110, since the height positions of the reference portions 142 of both reference members 116 are on the same flat plane, the probe 110 is stable relative to the support member by abutting the reference portions 142 on the underside of the support member, so that the probes 110 can be mounted on the support member by soldering and the like with the probes 110 maintained in such a state.

This facilitates mounting of the probes 110 on the support member, and enables to mount the probes 110 easily and accurately on the support member such that the height dimensions H0 from the support member to the tips of the probes 110 become the same. In the electrical connecting apparatus resulted from this, the height positions of the tips become the same.

The electrical connecting apparatus with the probes 110 assembled is incorporated in the electric testing apparatus. In such an electric testing apparatus, the reference portion 140 of the probe 110, of which the lower end face is detected by a sensor such as a video camera, is used to obtain an XY coordinate position of the probe 110 in the electric testing apparatus. The obtained XY coordinate position is used for a process for detecting and fixing the XY coordinate position of the probe 110, in particular, the tip relative to the electric testing apparatus.

As in case of the probe 110, if the tip member 114 has the contact portion 138 and the reference portion 140, the tip member 114 can be made of a single material. Hence, the physical relationship between the tip and the reference point can be made as per specification.

At the time of an electric test, in the probe 110, the lower end face (the tip) of the contact portion 138 is pressed against an electrode of a device under test. Because of this, an overdrive acts on the probe 110.

The probe 110, of which the body member 112, in particular, the arm portions 128, 130, are made of a metal material of a high tenacity as mentioned above, is elastically deformed greatly at the arm area 120, in particular, the arm portions 128, 130, and the lower end face of the contact portion 138 slides relative to the electrode of the device under test. The sliding amount at this time is great.

The lower end face of the contact portion 138 scrapes away an oxide film formed on the electrode by sliding relative to the electrode of the device under test. Since the tip member 114, in particular, the contact portion 138, is made of a metal material of high hardness, the amount of wear of the lower end face of the contact member 138 is small, and the probe 110 is long-lived.

In the probe 110, the lower end face of the reference portion 140 is retreated toward the base portion 136 to be higher than the lower end face of the contact portion 138, so that, even if the lower end face of the contact portion 138 is pressed against the electrode of the device under test, the reference portion 140 does not contact the device under test and the electrode thereof, thereby preventing damage.

In the foregoing probe 110, since the base portion 136 of the tip member 114 and both reference members 116 are respectively embedded in the pedestal portion 134 and the mounting portion 122 of the body member 112, the bonding strength between the body member 112 and the tip member 114 as well as the reference members 116 is strong.

In the probe 110, since the height positions of both reference portions 142 are the same, the upper end of the mounting portion 122, for instance, is not necessarily made a flat plane but may be made an irregular plane 144 as shown in FIG. 8. In this case, it suffices to have the reference portions 142 projected upward to be higher than the highest portion of the irregular plane 144.

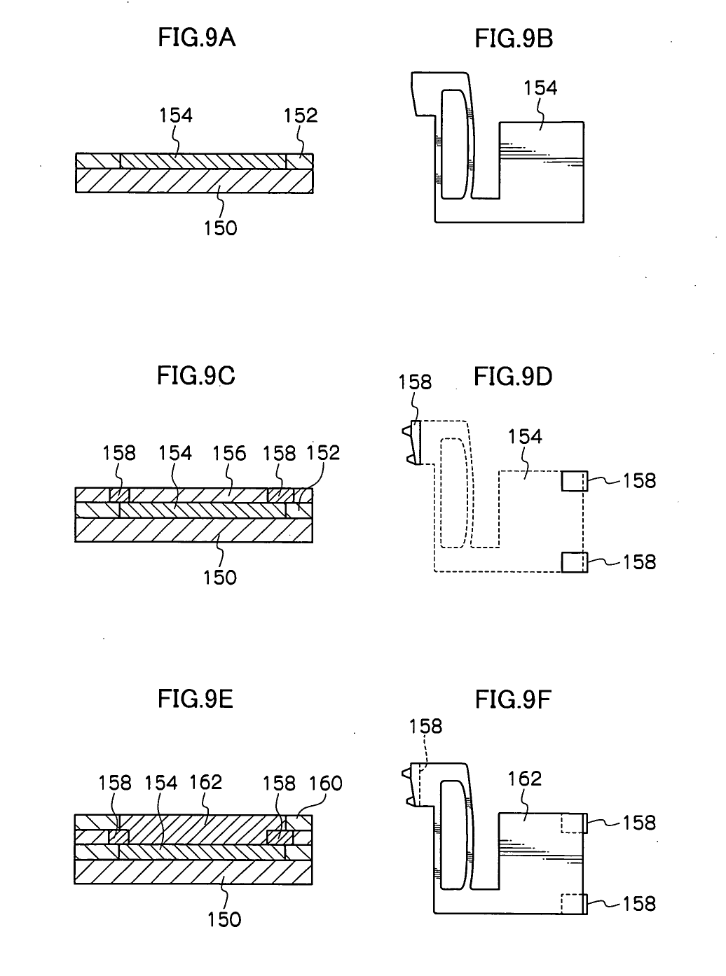

The probe 110 such as above can be made by using photolithographic technique and electroforming technique. Below is explained an example of producing the probe with reference to FIG. 9.

First, as shown in FIGS. 9(A) and 9(B), a base plate 150 is prepared, to which a photoresist 152 is applied. Of the photoresist 152, the area corresponding to the part of the body member 112 below the two-dot line 146 in FIG. 6 is exposed and developed, and then a recess is formed in the exposed and developed area. The recess is filled with a conductive metal material by electroplating which uses electroforming. The resulted filler 154 corresponds to a part of the body member 112.

Next, as shown in FIGS. 9(C) and 9(D), a photoresist 156 is applied to the photoresist 152 and the filler 154, and the area corresponding to the tip member 114 and both reference members 116 of the photoresist 156 is exposed and developed. In the exposed and developed area, recesses corresponding to the tip member 114 and both reference members 116 are formed. The recesses are filled with a conductive metal material by electroplating which uses electroforming. Resulted fillers 158 correspond to the tip member 114 and both reference members 116.

As shown in FIGS. 9(E) and 9(F), a photoresist 160 is applied to the photoresist 156 and the fillers 158. In the photoresist 160, the area corresponding to the remaining area of the body member 112 is exposed and developed. The recess corresponding to the remaining area of the body member 112 is formed with the photoresist 160 in the exposed and developed area, and the recess is filled with a conductive metal material by electroplating which uses electroforming. The resulted filler 162 corresponds to the remaining portion of the body member 112.

Later, all the photoresists 152, 156 and 160 are removed, and the probe having the fillers 154, 158 and 162 integrated therewith is removed from the base plate 150.

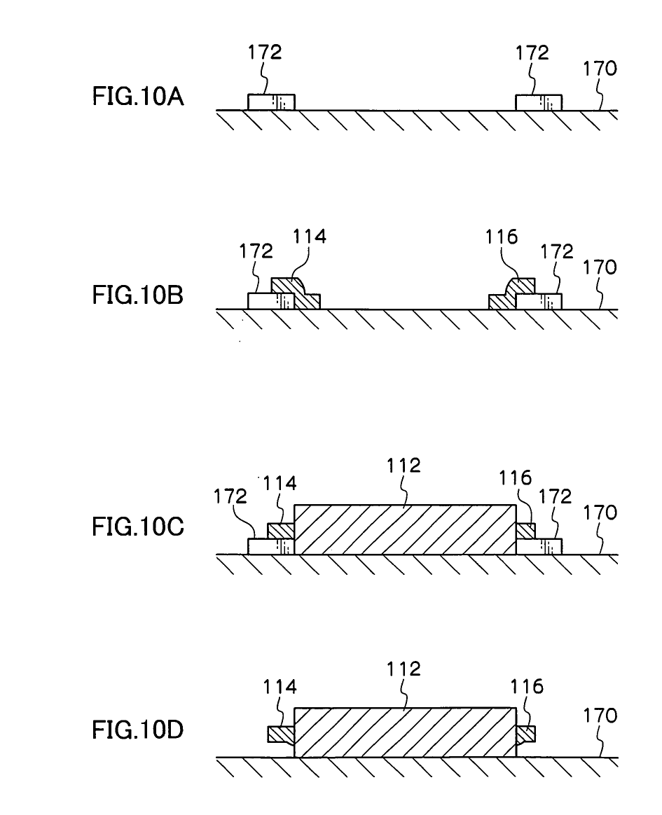

Below is explained another example of the method of producing probes with reference to FIG. 10.

First, as shown in FIG. 10(A), sacrifice layers 172 for the tip member 114 and both reference members 116 are made on a base plate 170 by photolithographic technique and electroforming technique.

Next, as shown in FIG. 10(B), the tip member 114 and both reference members 116 are made on the base plate 170 and the sacrifice layers 172 by photolithographic technique and electroforming technique.

Then, as shown in FIG. 10(C), the body member 112 is formed on the tip member 114 and both reference members 116 as well as the base plate 170 and the sacrifice layers 172 by photolithographic technique and electroforming technique.

Then, as shown in FIG. 10(D), the sacrifice layers 172 are removed. Later, the probe 110 including the body member 112, the tip member 114 and both reference members 116 is peeled off the base plate 170.

The probe 110 produced otherwise may have parts of the tip member 114 and both reference members 116 exposed on the side of the front face (or the reverse face side) of the body member 112.

According to either of the above-mentioned methods of production, the probe 110 with strong bonding between the body member 112, the tip member 114 and both reference members 116 can be produced easily in bulk and cheaply.

According to either of the above methods, if the tip member 114 and both reference members 116 are made at the same time in the same process, the tip member 114 and both reference members can be produced by using the same mask, so that, regardless of accuracy in overlapping the tip member 114 and both reference members 116 on the body member 112, the physical relationship between the tip and the reference portion 142 becomes constant. As a result, although it is possible to make the tip member 114 of a different material from the body member 112, multiple probes 110 with the same dimensional relationship between the tip member 114 and both reference members 116 can be made easily, in bulk, and cheaply.

It will be obvious to those having skill in the art that many changes may be made to the details of the above-described embodiments without departing from the underlying principles of the invention. The scope of the present invention should, therefore, be determined only by the following claims.

1. A probe for use in electric test comprising: a body member having a front end area and supported on a support member, and a tip member combined with said front end area of said body member,
wherein said tip member includes: a base portion with at least a part embedded in said front end area; a contact portion to be pressed against a device under test and projecting from said base portion in a second direction intersecting a first direction; and a reference portion formed at an interval from said contact portion in said first direction and projecting from said base portion in said second direction, and
wherein said tip member is made of a material harder than that of said body member.

2. A probe for use in electric test defined in claim 1, wherein said body member further includes a seat area having one end portion to be mounted on said support member and the other end portion opposing thereto; and an arm area extending from the other end portion of said seat area in said first direction, said front end area projecting from the front end of said arm area in the same direction as said contact portion and said reference portion of said tip member.

3. A probe for use in electric test defined in claim 2, wherein the base portion of said tip member is embedded in said front end area such that said contact portion and said reference portion project from said front end area in said second direction.

4. A probe for use in electric test defined in claim 1, wherein each of said contact portion and said reference portion has an end face directed toward the side opposite to said base portion side, and wherein the end face of said reference portion is retreated toward said base portion to be higher than the end face of said contact portion.

5. A probe for use in electric test, wherein said body member is made of a metal material selected from nickel, its alloy and phosphor bronze, and wherein said tip member is made of a metal material selected from cobalt, rhodium and their alloys.

6. A probe for use in electric test comprising: a body member having a seat area and an arm area, said seat area being mounted on a support member and said arm area extending from the lower end portions of said seat area in a lateral direction; a tip member having a tip projecting downward from the front end of said arm area; at least one reference member having a reference portion projecting upward from said seat area, wherein said tip member and said reference member are made of the same material and at least different from the material of said seat area.

7. A probe for use in electric test defined in claim 6, wherein a part of said reference member is embedded in said body member.

8. A probe for use in electric test defined in claim 6, wherein said probe comprises at least two reference members having said reference portion of the same height level at an interval in said lateral direction.

9. A probe for use in electric test defined in claim 7, wherein said reference portions include flat upper faces of the same height level.

10. A probe for use in electric test defined in claim 6, wherein said tip member and said reference member are made of a material harder than that of said body member.

11. A probe for use in electric test defined in claim 6, wherein said tip member includes a base portion with at least a part embedded in said arm area, a contact portion to be pressed against a device under test and projecting downward from said base portion, and a second reference portion formed at a position spaced apart from said contact portion and projecting downward from said base portion.
